(19) United States
(12) Patent Application Publication
(10) Pub. No.: US 2017/0179069 A1
(43) Pub. Date: Jun. 22, 2017

(54) BALL GRID ARRAY SOLDER ATTACHMENT

(71) Applicants: Jonathon R. Carstens, Lacey, WA (US); Michael S. Brazel, Fedeal Way, WA (US); Russell S. Aoki, Tacoma, WA (US); Laura S. Mortimer, lacey, WA (US)

(72) Inventors: Jonathon R. Carstens, Lacey, WA (US); Michael S. Brazel, Fedeal Way, WA (US); Russell S. Aoki, Tacoma, WA (US); Laura S. Mortimer, lacey, WA (US)

(21) Appl. No.: 14/974,807

(22) Filed: Dec. 18, 2015

(51) Int. Cl. H01L 23/00; B23K 3/06; B23K 1/00; B23K 3/08; H01L 23/498; H01L 23/34

(52) U.S. Cl. CPC H01L 24/81; H01L 23/49816; H01L 23/345; H01L 24/75; B23K 1/0016; B23K 3/082; B23K 3/06; H01L 2924/15321; H01L 2224/81815; H01L 2224/81234; H01L 2224/81024; H01L 2224/81035; H01L 2224/81007

(57) ABSTRACT

Reflow Grid Array (RGA) technology may be implemented on an interposer device, where the interposer is placed between a motherboard and a ball grid array (BGA) package. The interposer may provide a controlled heat source to reflow solder between the interposer and the BGA package. A technical problem faced by an interposer using RGA technology is application of solder to the RGA interposer. Technical solutions described herein provide processes and equipment for application of solder and formation of solder balls to connect an RGA interposer to a BGA package.

### TECHNICAL FIELD

Embodiments described herein generally relate to electrical interconnections in electronic devices.

### BACKGROUND

Circuit board assembly includes solder attachment of electronic components and electronic packages. The solder attachment provides both electrical and mechanical continuity. Electronic devices are decreasingly using dual in-line packages (DIP) or flat packages, and increasingly using ball grid array (BGA) packages. Similarly, servers and personal computers are decreasingly using socket packages (e.g., socket processor packages), and increasingly using BGA packages. BGA packages offer advantages over other packages, including reduced costs and lower Z-height attributes. Unlike a socket package that is designed to be inserted and removed without solder, a BGA package is a surface mount technology (SMT) that is soldered onto a motherboard. The soldering requirements of a BGA package require time and technical skill to apply solder to connect the BGA package with a motherboard. It is desirable to improve the use of BGA package technologies while reducing the difficulties associated with BGA package rework.

### BRIEF DESCRIPTION OF THE DRAWINGS

FIGS. 1A-1C are perspective diagrams of an RGA configuration, in accordance with at least one embodiment of the invention.

FIG. 2 is a block diagram of an RGA cross-section, in accordance with at least one embodiment of the invention.

FIG. 3 is a flowchart of a solder application method, in accordance with at least one embodiment of the invention.

FIG. 4 is a perspective diagram of a solder stencil, in accordance with at least one embodiment of the invention.

FIG. 5 is a perspective diagram of BGA stencil materials, in accordance with at least one embodiment of the invention.

FIG. 6 is a microscope image of a wet solder paste contact array, in accordance with at least one embodiment of the invention.

FIG. 7 is a flowchart of a solder application method, in accordance with at least one embodiment of the invention.

FIG. 8 is a perspective diagram of RGA interposer materials, in accordance with at least one embodiment of the invention.

FIG. 9 is a perspective diagram of RGA solder flux materials, in accordance with at least one embodiment of the invention.

FIG. 10 is a microscope image of an interposer solder bump array, in accordance with at least one embodiment of the invention.

FIG. 11 is a block diagram of a flux-ready RGA interposer, in accordance with at least one embodiment of the invention.

FIG. 12 is a perspective diagram of an interposer contact mask, in accordance with at least one embodiment of the invention.

FIGS. 13A-13B are block diagrams of solder mask bump formation, in accordance with at least one embodiment of the invention.

FIGS. 14A-14C are block diagrams of solder film deposition, in accordance with at least one embodiment of the invention.

FIG. 15 is a block diagram of an electronic device incorporating a solder apparatus or method in accordance with at least one embodiment of the invention.

### DESCRIPTION OF EMBODIMENTS

Reflow Grid Array (RGA) is a technology that provides technical solutions to technical problems facing BGA packages. RGA technology may be implemented on an interposer device, where the interposer is placed between a motherboard and a BGA package. The interposer may provide a controlled heat source to reflow solder between the interposer and the BGA package. The use of RGA technology in the interposer reduces the technical complexity of this BGA rework, and allows for late attachment or removal of BGA packages. The interposer provides more efficient CPU replacement and upgradability, such as allowing swapping processors during validation. The interposer also reduces costs associated with BGA package inventory management (e.g., stock-keeping unit (SKU) management, scrap electronics. The interposer provides several advantages over socket packaging, including lower cost, reduced power loss, lower load force, reduced height requirements, improved signal integrity, and others advantages.

A technical problem faced by an interposer using RGA technology is application of solder to the RGA interposer. Technical solutions described herein provide processes and equipment for application of solder and formation of solder balls to connect an RGA interposer to a BGA package.

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

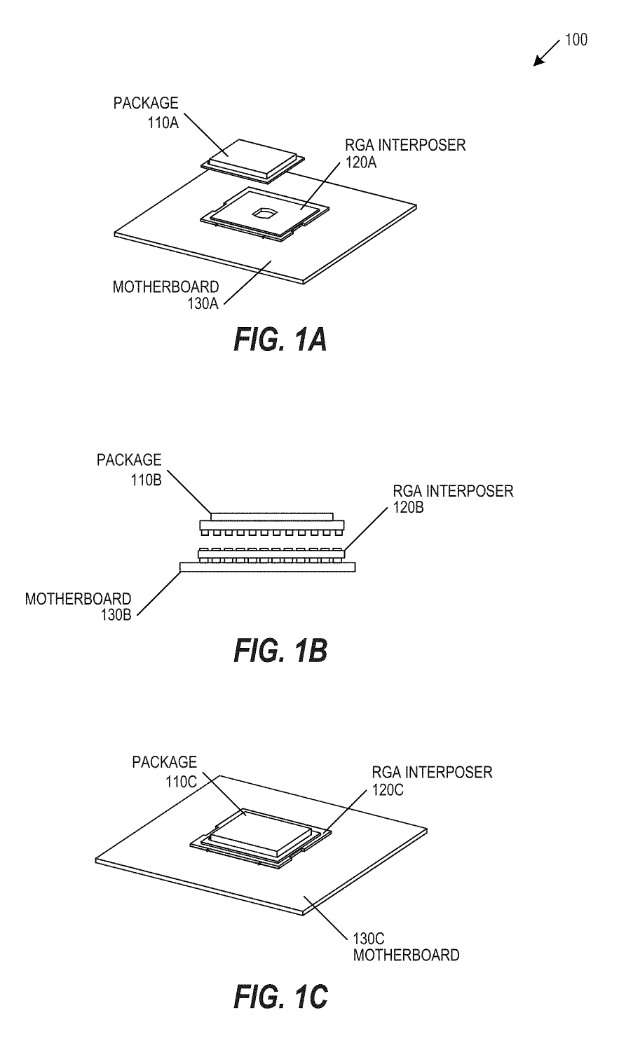

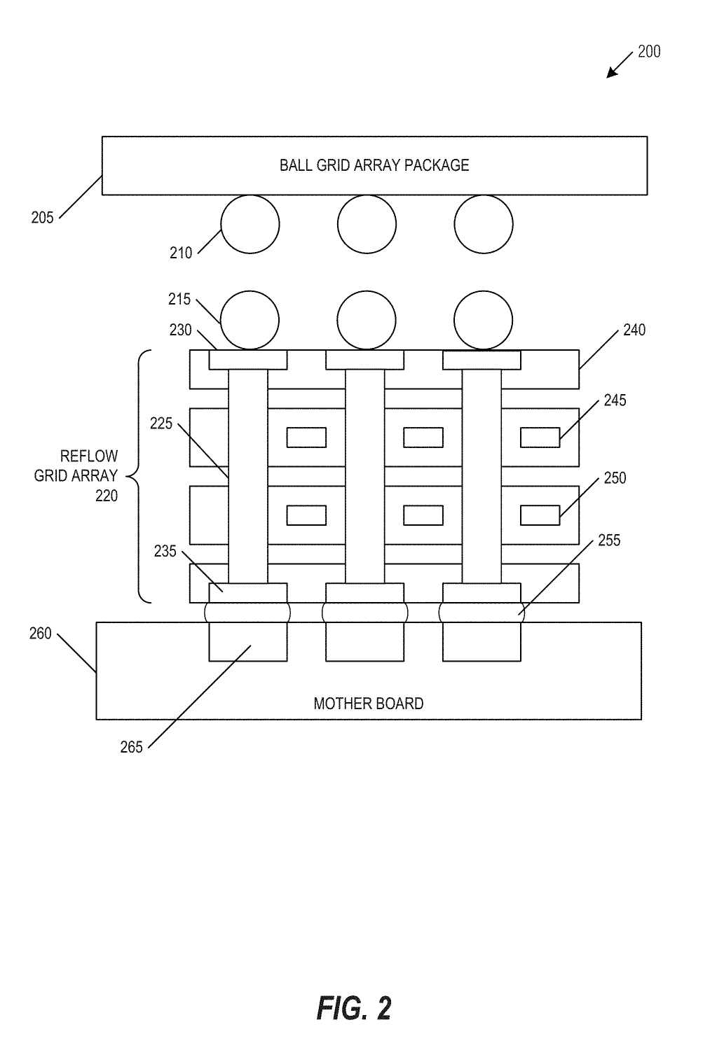

FIGS. 1A-1C are perspective diagrams of an RGA configuration 100, in accordance with at least one embodiment of the invention. FIG. 1A shows a separate BGA package 110A, an RGA interposer 120A, and a motherboard 130A. As shown in FIG. 1B, the RGA interposer 120B is attached to motherboard 130B, and provides an electrical conduit between contacts on the BGA package 110B and contacts on the motherboard 130B. The RGA interposer 120B may be soldered to the motherboard 130B by using the RGA interposer 120B to reflow solder between the RGA interposer 120B and the motherboard 130B. External heat may be provided to reflow solder between the RGA interposer 120B and the motherboard 130B. The RGA interposer 120B may be manufactured as a part of motherboard 130B. As shown in FIG. 1C, to attach the BGA package 130C, the BGA package 130C is placed on the interposer 120C. The RGA interposer 120C locally heats to reflow solder balls and attach the BGA package 130C to the interposer 120C. A cross-section of an RGA configuration 100 is shown in FIG. 2.

FIG. 2 is a block diagram of an RGA cross-section 200, in accordance with at least one embodiment of the invention. The RGA cross-section 200 includes a BGA package 205, an RGA interposer 220, and a motherboard 260. The interposer 220 includes at least one plated through-hole 225 that provides an electric connection between the top and bottom of the interposer. The plated through-hole 225 is connected to an upper interposer pad 230 and a lower interposer pad 235. The plated through-hole spans through at least one interposer dielectric layer 240. An interposer dielectric layer 240 includes a heater trace 245. The heater trace 245 may include a copper trace, or other heat-conductive material. An interposer dielectric layer 240 includes a thermal sensor trace 250. The thermal sensor trace 250 may be on the same interposer dielectric layer 240 as the heater trace 245, or may be on a different interposer dielectric layer 240.

The RGA interposer 220 may be used to connect the RGA interposer 220 to the motherboard 260. The heater trace 245 reflows solder 215 on the RGA interposer 220, where solder 255 connects the lower interposer pads 235 to the motherboard contacts 265. The heater trace 245 and sensor trace 250 may be connected to an external controller, where the external controller may be used to control the heater current while monitoring surface temperatures. Multiple heater traces 245 and sensor traces 250 may be used to control heat to specific zones on the interposer, where the specific zones may be used to reflow a portion of the adjacent solder balls. The interposer may be used in joining or separating the interposer from the motherboard, or in joining or separating a BGA package from the interposer.

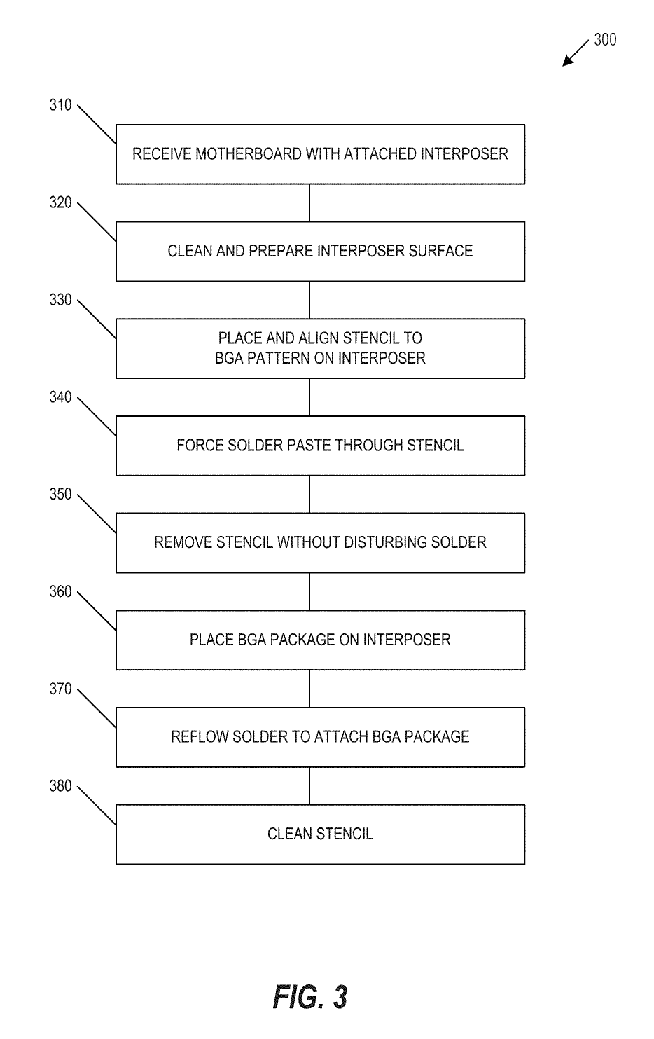

To connect the BGA package 205 to the RGA interposer 220, the BGA package 205 is placed on the RGA interposer 220, and heater trace 245 provides heat to reflow solder 215 and solder 210. Many BGA packages include attached solder balls, such as BGA package 205 and solder balls 210. A separate arrangement of solder deposits 215 are applied to each of the upper interposer pads 230 to allow solder 215 and solder 210 to provide an appropriate electrical and mechanical connection between the BGA package 205 and the RGA interposer 220. There are a number of technical challenges involved in applying solder 215 to upper interposer pads 230. In a typical IC device, as many as several thousand interconnection pads may require careful application of solder onto each pad. One method of applying solder is described with respect to FIG. 3.

FIG. 3 is a flowchart of a solder application method 300, in accordance with at least one embodiment of the invention. Solder application method 300 includes receiving 310 a motherboard with an attached interposer, and includes cleaning and preparing 320 the interposer surface. A porous stencil (e.g., resist pattern) including multiple interposer contact pores is then placed 330 on the interposer and aligned to the interposer contacts. Solder paste is applied to and forced 340 through the stencil, applying a small amount of solder paste to each of the interposer contacts. The amount of solder paste applied to and forced 340 through the stencil must be carefully controlled. For example, applying too much solder may bridge multiple contacts on the interposer, and applying too little solder may prevent a contact from being made between the interposer and a BGA package. The stencil is then removed 350, where removal must be performed with sufficient precision so as not to smear the solder paste applied to the interposer contacts. A BGA package is then placed 360 on the interposer, and the solder is reflowed 370 to attach the BGA package to the interposer. Finally, the stencil is cleaned 380 to prepare for the next BGA package attachment. While the solder application method 300 is described with respect to a motherboard with attached interposer, a similar solder application method 300 is applicable to attach a BGA to a motherboard without an interposer.

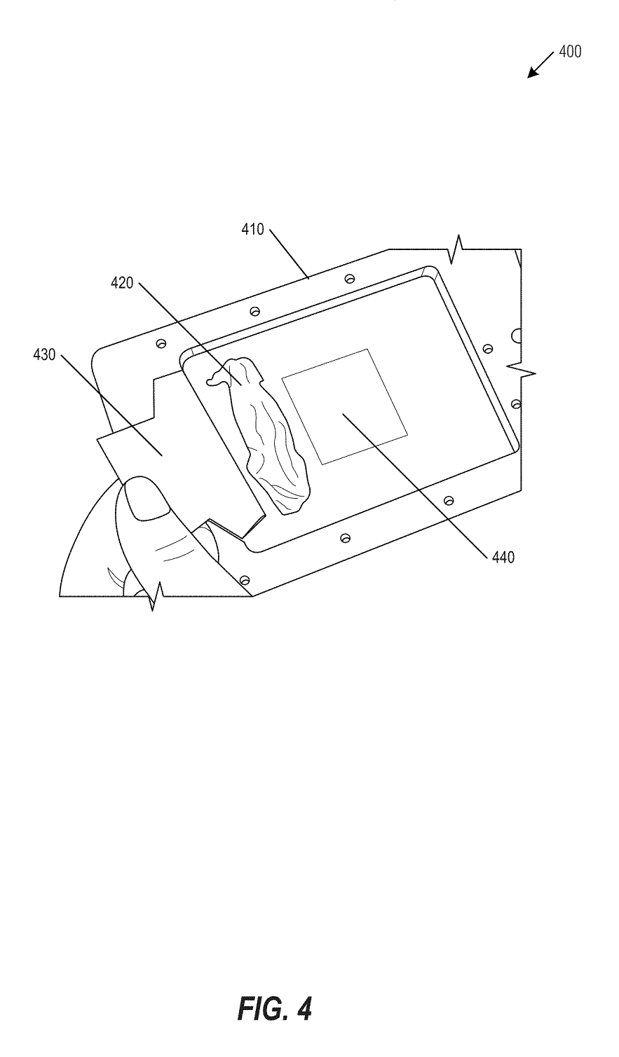

FIG. 4 is a perspective diagram of a solder stencil 400, in accordance with at least one embodiment of the invention. Solder stencil 400 includes a stencil housing 410 onto which solder paste 420 is applied. The solder stencil is arranged on an interposer or directly on a motherboard. The solder stencil is arranged carefully such that pores in a solder paste screen 440 align with corresponding contacts on the motherboard or interposer. A solder paste application flange 430 or solder squeegee (not shown) is used to force the solder paste 420 through a solder screen 440. Once the solder paste 420 is applied, the solder stencil 400 must be removed carefully to avoid smearing the solder paste between any contacts on the motherboard or interposer.

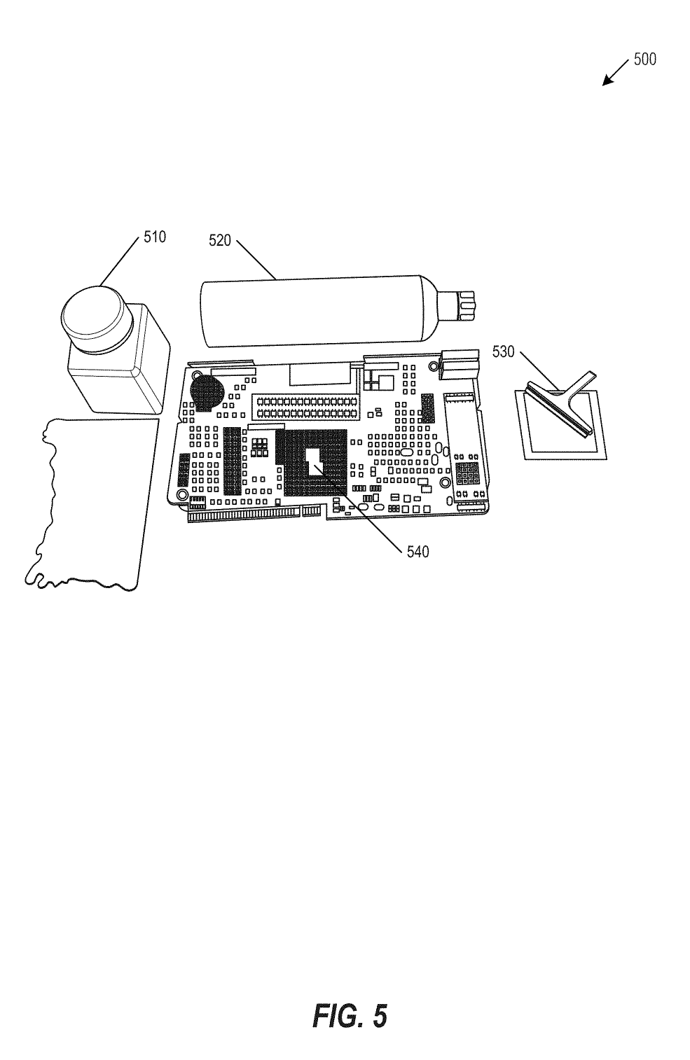

FIG. 5 is a perspective diagram of BGA stencil materials 500, in accordance with at least one embodiment of the invention. FIG. 5 shows materials used in certain methods of BGA package attachment. For example, solder paste application may require cleaning materials 510, solder paste 520, a solder stencil and squeegee 530, and a BGA-compatible motherboard 540.

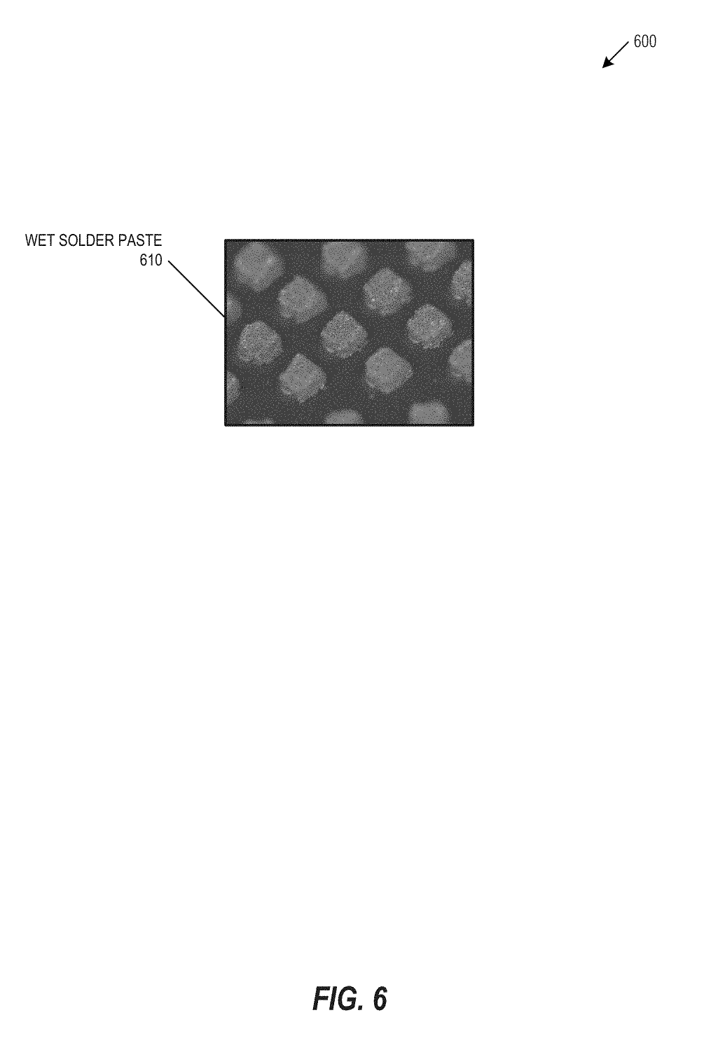

FIG. 6 is a microscope image of a wet solder paste contact array 600, in accordance with at least one embodiment of the invention. The contact array 600 includes wet solder paste 610 applied to each of the contacts, such as using the solder application method 300. The wet solder paste 610 may not be applied in uniform amounts to each contact, and is subject to smearing, such as when applying or removing a solder paste stencil.

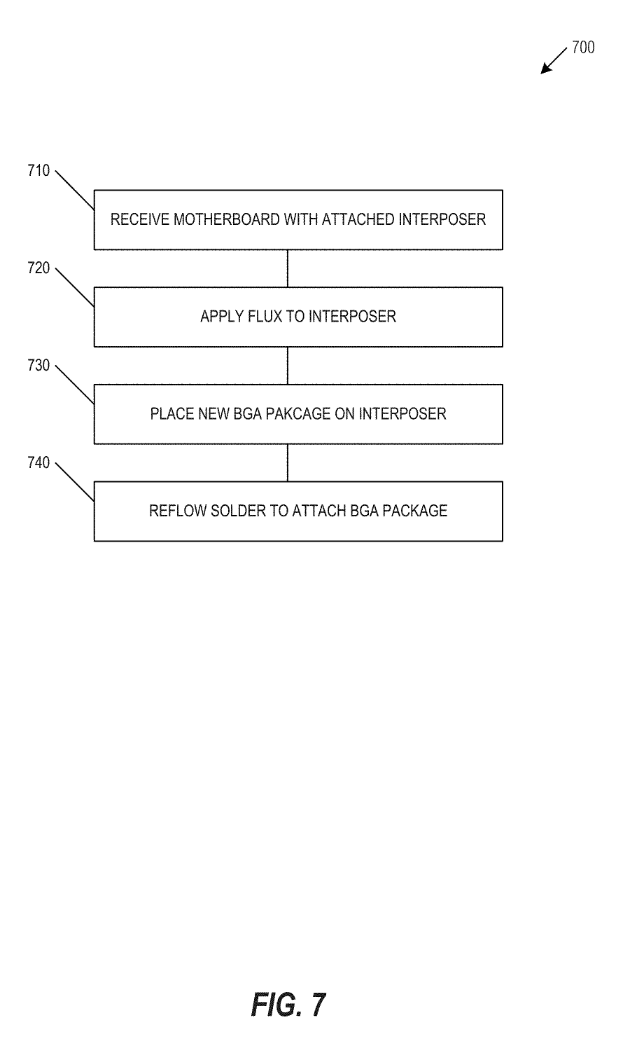

FIG. 7 is a flowchart of a solder application method 700, in accordance with at least one embodiment of the invention. Solder application method 700 includes receiving 710 a motherboard with an attached interposer. In contrast with the interposer used in solder application method 300, this interposer includes solder disposed on each of the interposer contacts. Solder flux is then applied 720 to the interposer contacts. Application 720 of solder flux may include sweeping the solder flux across the interposer to coat interposer contacts. However, in contrast with the application of solder to individual interposer contacts in solder application method 300, flux is used to clean and reduce oxidation of existing contacts and solder deposits, so the flux may be applied as a layer of flux across the entire interposer surface. A BGA package is then placed 730 on the interposer, and the solder is reflowed 740 to attach the BGA package to the interposer. Method 700 alleviates the need for a stencil, precision application of solder paste through a stencil, or cleaning of a stencil.

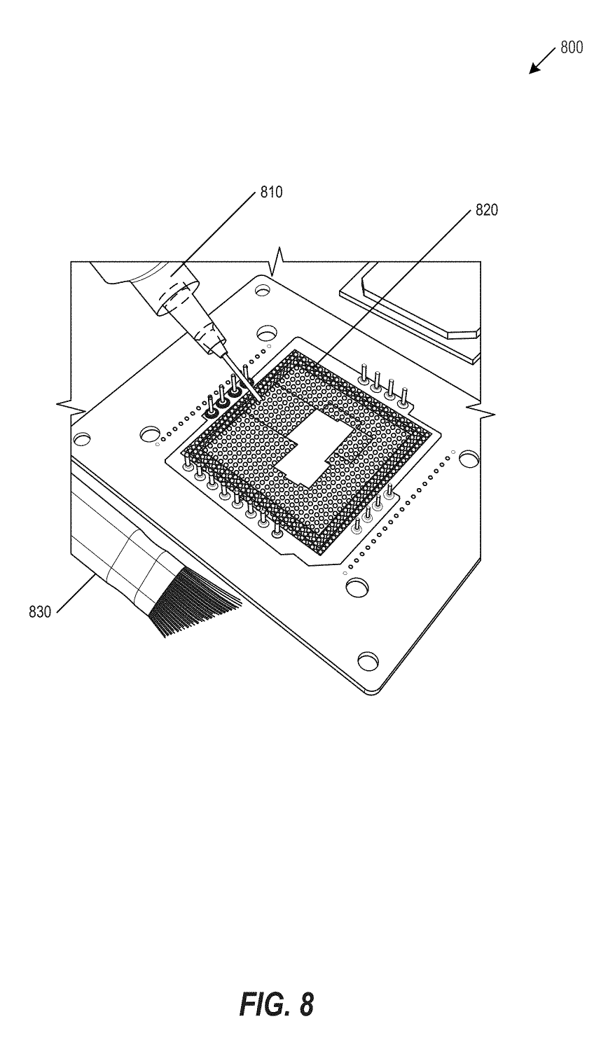

FIG. 8 is a perspective diagram of RGA interposer materials 800, in accordance with at least one embodiment of the invention. FIG. 8 shows materials used for a method of BGA package attachment using an RGA interposer. For example, a flux applicator 810 may be used to apply flux to multiple contacts on an RGA interposer 820. The flux may be spread across the surface of the RGA interposer 820 using a flux brush 830. This is in contrast with the precise application of solder paste required in solder application method 300 described above, and in contrast with the longer list of BGA stencil materials 500 described above.

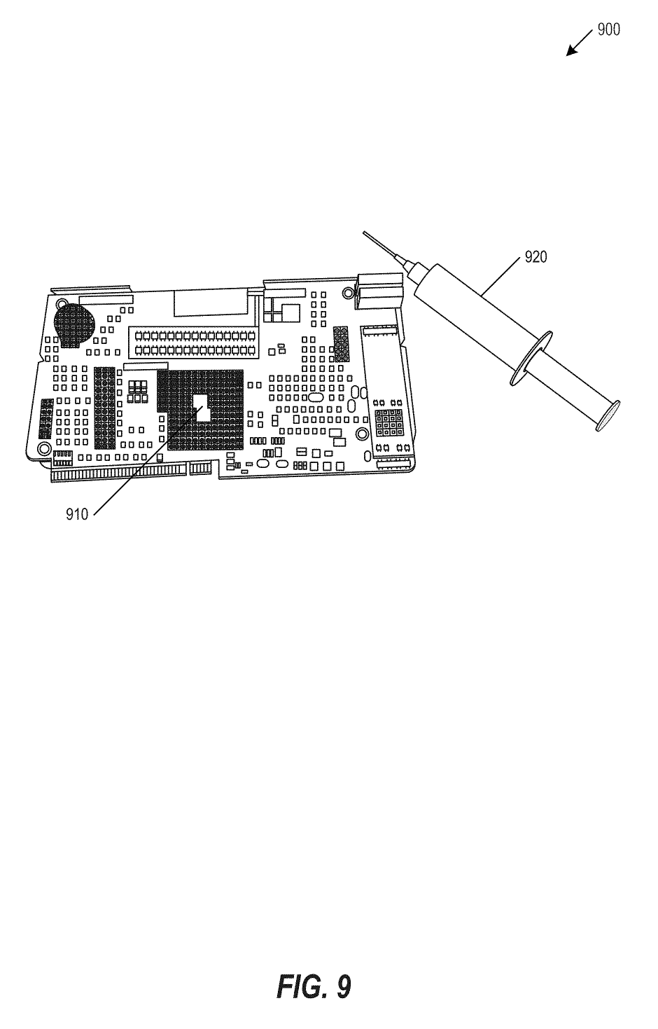

FIG. 9 is a perspective diagram of RGA solder flux materials 900, in accordance with at least one embodiment of the invention. FIG. 9 shows materials used in a proposed method of BGA package attachment. For example, BGA package attachment using an RGA requires an RGA interposer 910 and solder flux 920. These few RGA solder flux materials 900 are in contest with the many materials required for a BGA solder paste stencil, such as BGA stencil materials 500 described above.

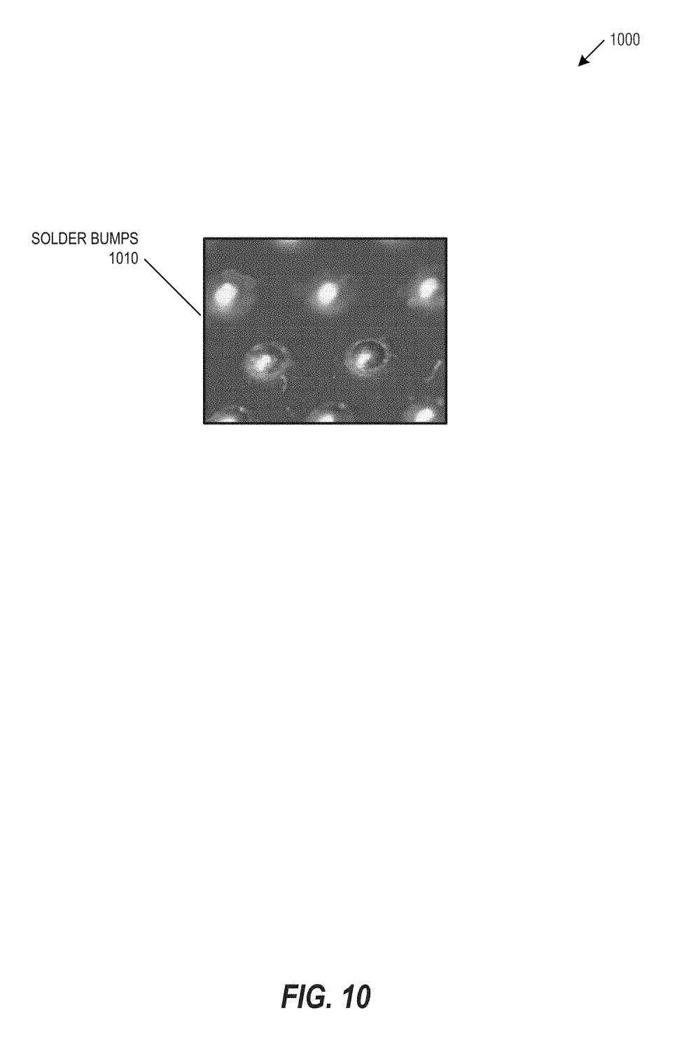

FIG. 10 is a microscope image of an interposer solder bump array 1000, in accordance with at least one embodiment of the invention. The solder bump array 600 includes solidified solder that was previously reflowed on an interposer surface to form solder bumps 1010. The solder bumps 1010 are solid, and are not subject to the same smearing as the wet solder paste 610 used in solder application method 300 described above.

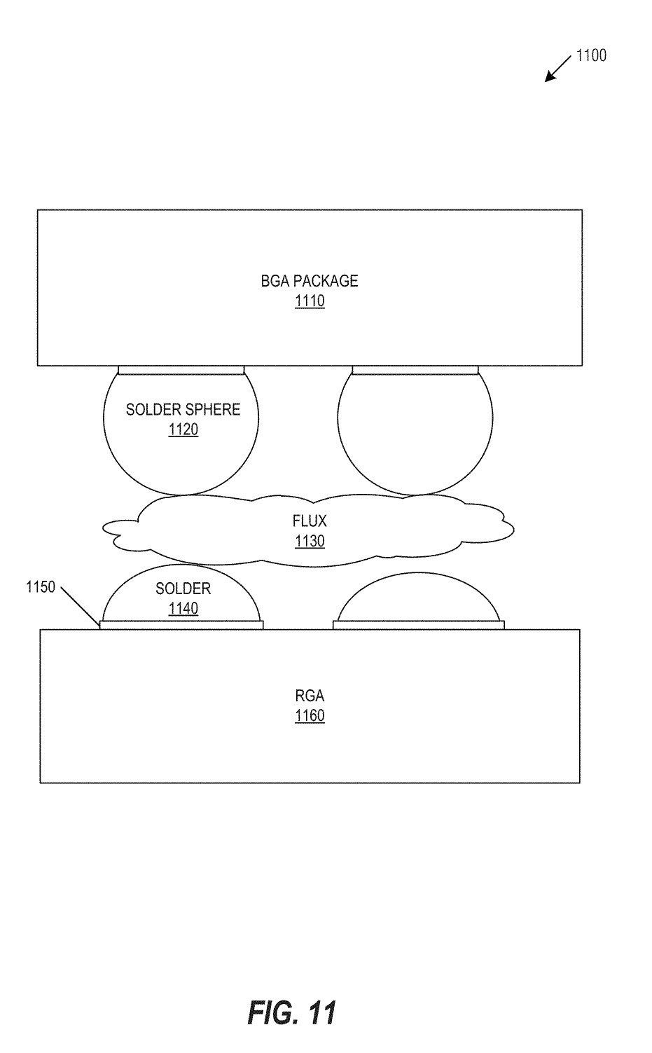

FIG. 11 is a block diagram of a flux-ready RGA interposer 1100, in accordance with at least one embodiment of the invention. Flux-ready RGA interposer 1100 may be connected to a BGA package by applying only flux, such as using method 700. An RGA 1150 may include multiple contacts 1150, where each contact includes a solder deposit 1140. Each solder deposit 1140 may be formed from a low temperature solder that was previously reflowed and is now solid. A layer of flux 1130 is applied across all of the solder deposits 1140. A BGA package 1110 includes multiple solder spheres 1120. The solder spheres 1120 may be formed from high temperature solder that was previously reflowed and is now solid. The BGA 1110 package is lowered onto the RGA 1150 such that each of the solder spheres 1120 is positioned over a corresponding solder deposit 1140. An alignment housing (not shown) may be used to align the solder spheres 1120 with the solder deposits 1140. The RGA interposer 1100 applies heat to the solder deposits 1140 and solder spheres 1120, causing each to reflow and form a soldered connection. The use of a low temperature solder for the solder deposit 1140 and a high temperature solder for the solder spheres 1120 may allow for a controlled reflow process. For example, the RGA interposer 1100 may reflow the solder deposit 1140 at a lower temperature to form a rounded or spherical solder deposit due to the surface tension of solder. Once the solder deposits 1140 have formed a desired shape, the RGA interposer 1100 may reflow the solder spheres 1120 at a higher temperature to form a solder connection between the solder deposits 1140 and solder spheres 1120. The use of various temperatures may also be used to allow the flux to clean the solder deposits 1140 or solder spheres 1120.

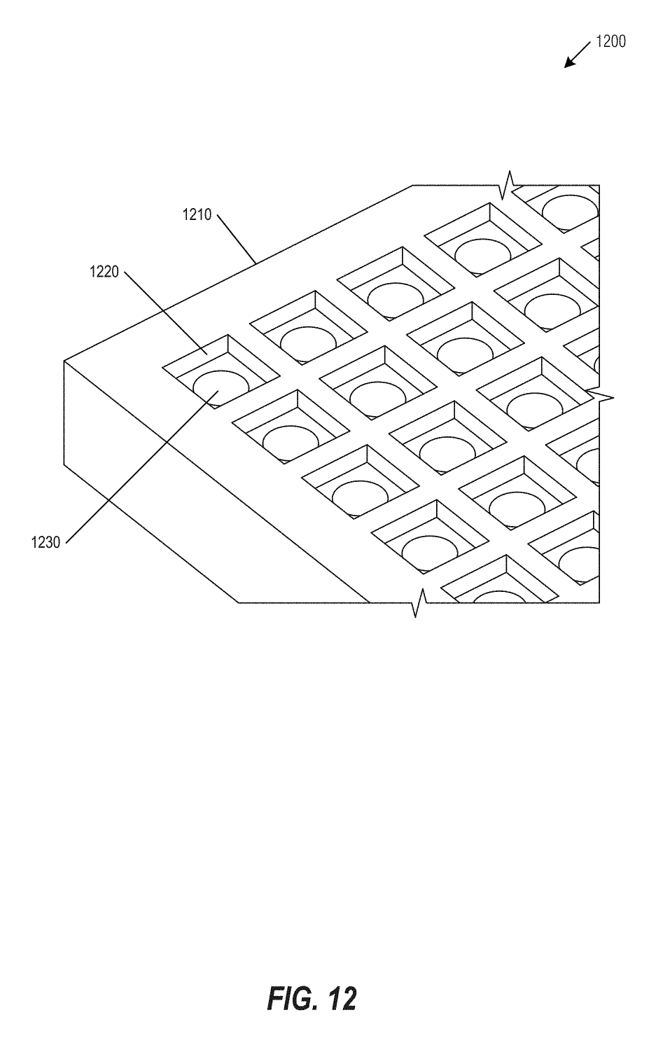

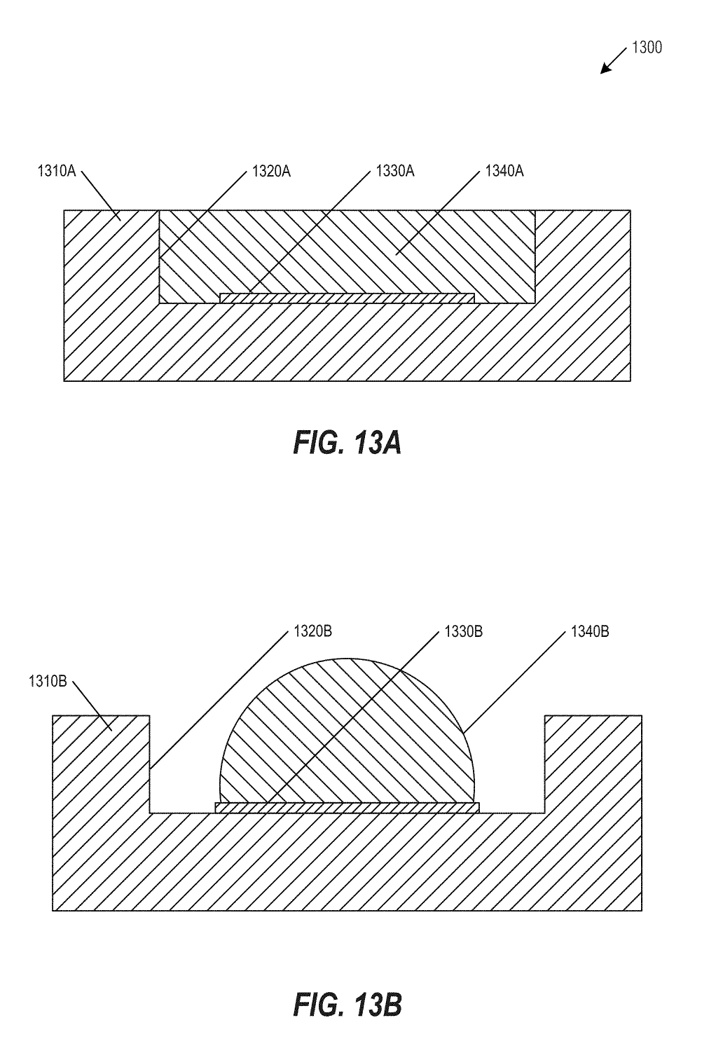

FIG. 12 is a perspective diagram of an interposer contact mask 1200, in accordance with at least one embodiment of the invention. The contact mask 1200 includes a contact mask housing 1210, where the contact mask housing 1210 includes multiple mask spaces (e.g., apertures) 1220 corresponding to each of the multiple contacts 1230 on an RGA interposer. Contact mask 1200 may be a separate structure that is placed on an RGA interposer. Contact mask 1200 may be formed as a part of an RGA interposer, such as using an additional layer of interposer fiberglass dielectric or a thick layer of a solder resist mask. The contact mask 1200 may be used to form solder bumps, such as shown in FIGS. 13A-13B.

FIGS. 13A-13B are block diagrams of solder mask bump formation 1300, in accordance with at least one embodiment of the invention. FIG. 13A shows an interposer contact mask 1310A that includes a mask space 1320A and an interposer contact 1330A. Solder 1340A is placed within the mask space 1320A. In an example, solder paste is applied to the mask space 1320A, and excess solder paste may be removed from the interposer contact mask 1310A. FIG. 13B shows the configuration of FIG. 13A after the solder has been reflowed. When the RGA interposer applies heat to the interposer contact 1330B, the solder 1340B reflows, and solder surface tension causes the solder 1340B to form a curved or spherical shape. The interposer and shaped solder 1340B may then be used in the flux-ready RGA interposer 1100 as described above.

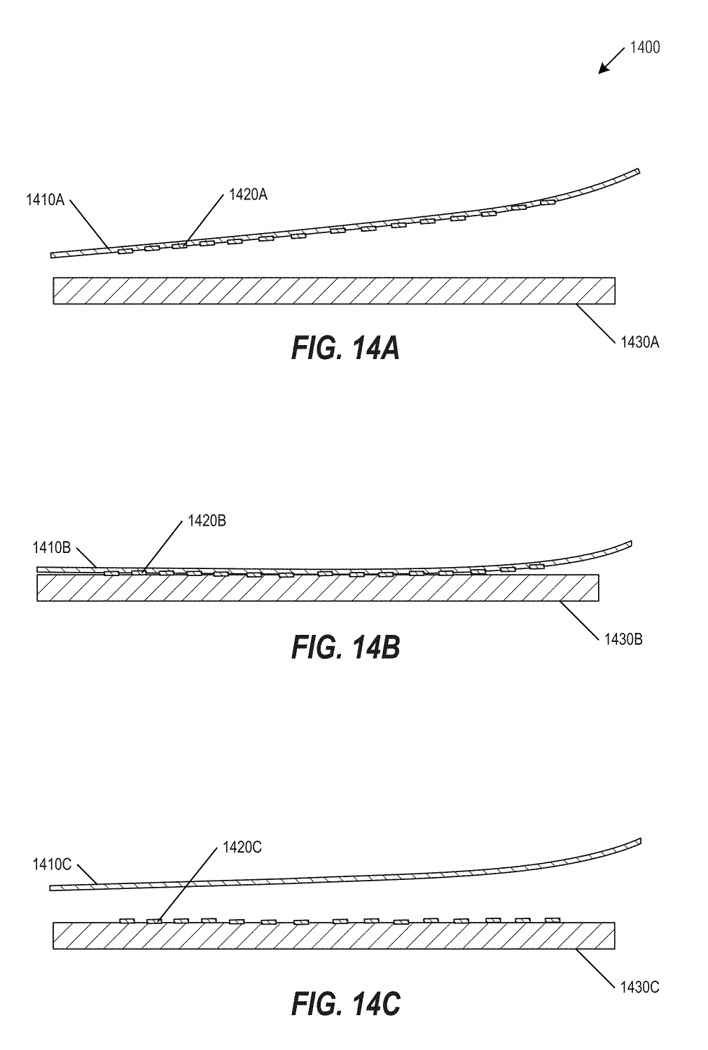

FIGS. 14A-14C are block diagrams of solder film deposition 1400, in accordance with at least one embodiment of the invention. As shown in FIG. 14A, solder film deposition 1400 includes a solder deposition film 1410A that includes multiple solder deposits 1420A. The solder deposits 1420A may be applied to the solder deposition film 1410A as a solder paste, as adhesive solder deposits, or in another solder form. FIG. 14B shows solder deposition film 1410B and solder deposits 1420B applied to the surface of an RGA interposer 1430B. As shown in FIG. 14C, the solder deposition film 1410C may be removed, leaving the solder deposits 1420C on the interposer 1430C. The solder deposition film 1410C may be removed by peeling, dissolving, or another method. Solder deposition film 1410C and solder deposits 1420C may be applied RGA interposer 1430C with or without the use of an interposer contact mask 1200. Once applied, the interposer 1430C reflows the solder deposits 1420C to form solder spheres. The interposer 1430C and reflowed solder deposits 1420C may then be used in the flux-ready RGA interposer 1100 as described above.

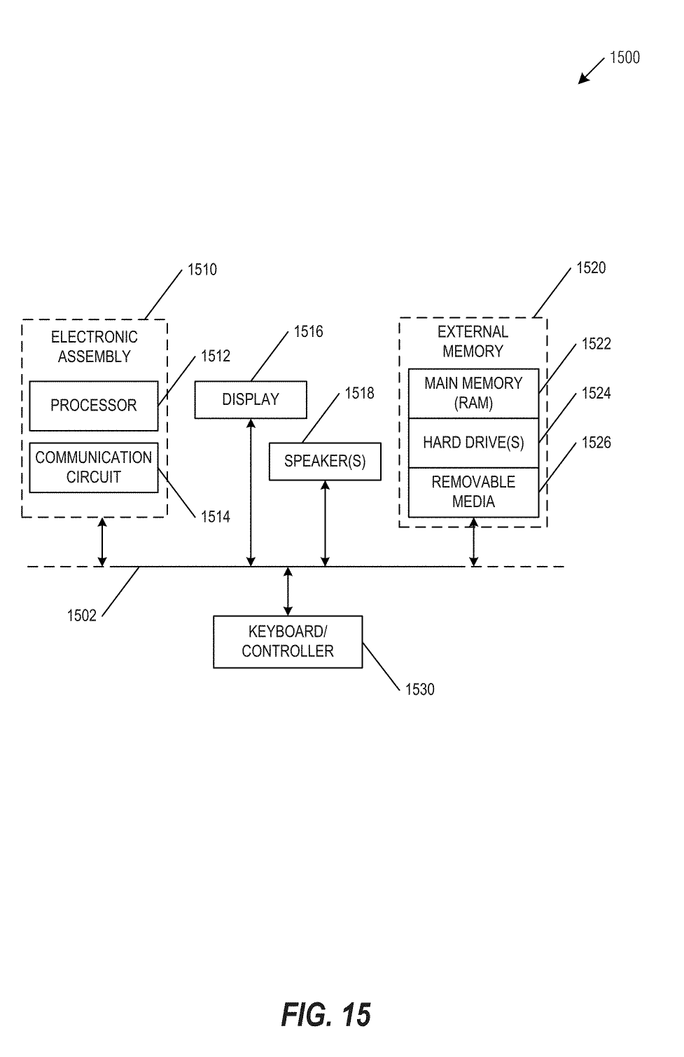

FIG. 15 is a block diagram of an electronic device 1500 incorporating a solder apparatus or method in accordance with at least one embodiment of the invention. FIG. 15 shows an example of an electronic device using semiconductor chip assemblies and solders as described in the present disclosure is included to show an example of a higher-level device application for the present invention. Electronic device 1500 is merely one example of an electronic system in which embodiments of the present invention can be used. Examples of electronic devices 1500 include, but are not limited to personal computers, tablet computers, mobile telephones, game devices, MP3 or other digital music players, etc. In this example, electronic device 1500 comprises a data processing system that includes a system bus 1502 to couple the various components of the system. System bus 1502 provides communications links among the various components of the electronic device 1500 and can be implemented as a single bus, as a combination of busses, or in any other suitable manner.

An electronic assembly 1510 is coupled to system bus 1502. The electronic assembly 1510 can include any circuit or combination of circuits. In one embodiment, the electronic assembly 1510 includes a processor 1512 that can be of any type. As used herein, “processor” means any type of computational circuit, such as but not limited to a microprocessor, a microcontroller, a complex instruction set computing (CISC) microprocessor, a reduced instruction set computing (RISC) microprocessor, a very long instruction word (VLIW) microprocessor, a graphics processor, a digital signal processor (DSP), multiple core processor, or any other type of processor or processing circuit.

Other types of circuits that can be included in electronic assembly 1510 are a custom circuit, an application-specific integrated circuit (ASIC), or the like, such as, for example, one or more circuits (such as a communications circuit 1514) for use in wireless devices like mobile telephones, personal data assistants, portable computers, two-way radios, and similar electronic systems. The IC can perform any other type of function.

The electronic device 1500 can also include an external memory 1520, which in turn can include one or more memory elements suitable to the particular application, such as a main memory 1522 in the form of random access memory (RAM), one or more hard drives 1524, and/or one or more drives that handle removable media 1526 such as compact disks (CD), flash memory cards, digital video disk (DVD), and the like.

The electronic device 1500 can also include a display device 1516, one or more speakers 1518, and a keyboard and/or controller 1530, which can include a mouse, trackball, touch screen, voice-recognition device, or any other device that permits a system user to input information into and receive information from the electronic device 1500.

To better illustrate the method and apparatuses disclosed herein, a non-limiting list of embodiments is provided here:

Example 1 is a method comprising: disposing solder on each of a plurality of interposer contacts on a reflow grid array (RGA) interposer; and reflowing the solder to form solid solder bumps, the solid solder bumps configured to be reflowed by the RGA interposer to solder an electrical component to the RGA interposer.

In Example 2, the subject matter of Example 1 optionally includes wherein reflowing the solder includes heating an interposer heater trace.

In Example 3, the subject matter of any one or more of Examples 1-2 optionally include soldering the electrical component to the RGA interposer.

In Example 4, the subject matter of Example 3 optionally includes wherein the electrical component includes a ball grid array (BGA) component.

In Example 5, the subject matter of any one or more of Examples 3-4 optionally include wherein soldering the electrical component includes applying flux to the solid solder bumps.

In Example 6, the subject matter of Example 5 optionally includes wherein soldering the electrical component includes disposing the electrical component on the RGA interposer.

In Example 7, the subject matter of any one or more of Examples 5-6 optionally include wherein soldering the electrical component includes aligning the solid solder bumps with a plurality of component contacts on the electrical component.

In Example 8, the subject matter of Example 7 optionally includes wherein aligning the solid solder bumps includes disposing an alignment fixture on the RGA interposer and disposing the electrical component within the alignment fixture.

In Example 9, the subject matter of any one or more of Examples 3-8 optionally include wherein soldering the electrical component includes reflowing the solid solder bumps.

In Example 10, the subject matter of Example 9 optionally includes wherein soldering the electrical component includes reflowing a plurality of electrical component solder bumps on the electrical component to form electrical contacts between the plurality of electrical component solder bumps and the solid solder bumps.

In Example 11, the subject matter of any one or more of Examples 1-10 optionally include wherein disposing solder on each of the plurality of interposer contacts includes disposing solder in each of a plurality of vacant spaces within an interposer contact mask, the plurality of vacant spaces corresponding to the plurality of interposer contacts.

In Example 12, the subject matter of Example 11 optionally includes wherein disposing solder includes disposing a solder resist material.

In Example 13, the subject matter of any one or more of Examples 11-12 optionally include wherein the interposer contact mask includes a dielectric material.

In Example 14, the subject matter of Example 13 optionally includes wherein the dielectric material includes a fiberglass material.

In Example 15, the subject matter of any one or more of Examples 11-14 optionally include wherein disposing solder includes disposing the interposer contact mask on the RGA interposer.

In Example 16, the subject matter of any one or more of Examples 11-15 optionally include wherein the interposer contact mask is formed on the RGA interposer.

In Example 17, the subject matter of any one or more of Examples 1-16 optionally include wherein disposing the solder includes disposing a solder film on the RGA interposer, the solder film applying a pre-dispensed solder paste deposit on each of a plurality of interposer contacts.

In Example 18, the subject matter of Example 17 optionally includes wherein the solder film is shaped to align with the RGA interposer to align the pre-dispensed solder paste deposit with the plurality of interposer contacts.

Example 19 is a method comprising: applying flux to solid solder bumps on a reflow grid array (RGA) interposer; disposing an electrical component on the RGA interposer; and soldering the electrical component to the RGA interposer.

In Example 20, the subject matter of Example 19 optionally includes wherein the electrical component includes a ball grid array (BGA) component.

In Example 21, the subject matter of any one or more of Examples 19-20 optionally include wherein soldering the electrical component includes reflowing the solid solder bumps.

In Example 22, the subject matter of Example 21 optionally includes wherein soldering the electrical component includes reflowing a plurality of electrical component solder bumps on the electrical component to form electrical contacts between the plurality of electrical component solder bumps and the solid solder bumps.

In Example 23, the subject matter of any one or more of Examples 19-22 optionally include wherein soldering the electrical component includes aligning the solid solder bumps with a plurality of component contacts on the electrical component.

In Example 24, the subject matter of Example 23 optionally includes wherein aligning the solid solder bumps includes disposing an alignment fixture on the RGA interposer and disposing the electrical component within the alignment fixture.

Example 25 is a machine-readable medium including instructions, which when executed by a computing system, cause the computing system to perform any of the methods of Examples 1-18.

Example 26 is an apparatus comprising means for performing any of the methods of Examples 1-18.

Example 27 is a machine-readable medium including instructions, which when executed by a computing system, cause the computing system to perform any of the methods of Examples 19-24.

Example 28 is an apparatus comprising means for performing any of the methods of Examples 19-24.

Example 29 is an apparatus comprising: a reflow grid array (RGA) interposer including a heater trace and a plurality of interposer contacts; solid solder bumps reflowed on each of the plurality of interposer contacts.

In Example 30, the subject matter of Example 29 optionally includes an electrical component soldered to the RGA interposer, wherein the heating element is configured to reflow the solid solder bumps to solder the electrical component to the RGA interposer.

In Example 31, the subject matter of Example 30 optionally includes wherein the electrical component includes a ball grid array (BGA) component.

In Example 32, the subject matter of any one or more of Examples 30-31 optionally include an alignment fixture to align the electrical component with the RGA interposer.

In Example 33, the subject matter of any one or more of Examples 30-32 optionally include wherein the heating element is configured to reflow a plurality of electrical component solder bumps on the electrical component to form electrical contacts between the plurality of electrical component solder bumps and the solid solder bumps.

Example 34 is an apparatus comprising: a reflow grid array (RGA) interposer including a heater trace and a plurality of interposer contacts; and an RGA interposer solder application device to facilitate application of a solder deposit to each of the plurality of interposer contacts, the heater trace configured to reflow the solder deposit to form solid solder bumps on each of the plurality of interposer contacts.

In Example 35, the subject matter of Example 34 optionally includes wherein the RGA interposer solder application device includes an interposer contact mask, the interposer contact mask including a plurality of mask spaces corresponding to the plurality of interposer contacts.

In Example 36, the subject matter of Example 35 optionally includes wherein the interposer contact mask includes a contact mask solder deposit within each of the plurality of mask spaces.

In Example 37, the subject matter of any one or more of Examples 35-36 optionally include wherein the interposer contact mask includes a solder resist material.

In Example 38, the subject matter of any one or more of Examples 35-37 optionally include wherein the interposer contact mask includes a dielectric material.

In Example 39, the subject matter of Example 38 optionally includes wherein the interposer contact mask includes a fiberglass material.

In Example 40, the subject matter of any one or more of Examples 35-39 optionally include wherein the interposer contact mask is disposed on the RGA interposer.

In Example 41, the subject matter of any one or more of Examples 35-40 optionally include wherein the interposer contact mask is formed on the RGA interposer.

In Example 42, the subject matter of any one or more of Examples 34-41 optionally include wherein the RGA interposer solder application device includes a solder film, the solder film configured to dispose a solder film solder deposit on each of the plurality of interposer contacts.

In Example 43, the subject matter of Example 42 optionally includes wherein the solder film is shaped to align the solder film solder deposit with each of the plurality of interposer contacts.

Example 44 is at least one machine-readable storage medium, comprising a plurality of instructions that, responsive to being executed with processor circuitry of a computer-controlled device, cause the computer-controlled device to: dispose solder on each of a plurality of interposer contacts on a reflow grid array (RGA) interposer; and reflow the solder to form solid solder bumps, the solid solder bumps configured to be reflowed by the RGA interposer to solder an electrical component to the RGA interposer.

In Example 45, the subject matter of Example 44 optionally includes wherein the instructions cause the computer-controlled device to heat an interposer heater trace.

In Example 46, the subject matter of any one or more of Examples 44-45 optionally include wherein the instructions cause the computer-controlled device to solder electrical component to the RGA interposer.

In Example 47, the subject matter of Example 46 optionally includes wherein the electrical component includes a ball grid array (BGA) component.

In Example 48, the subject matter of any one or more of Examples 46-47 optionally include wherein the instructions cause the computer-controlled device to apply flux to the solid solder bumps.

In Example 49, the subject matter of Example 48 optionally includes wherein the instructions cause the computer-controlled device to dispose the electrical component on the RGA interposer.

In Example 50, the subject matter of any one or more of Examples 48-49 optionally include wherein the instructions cause the computer-controlled device to align the solid solder bumps with a plurality of component contacts on the electrical component.

In Example 51, the subject matter of Example 50 optionally includes wherein the instructions cause the computer-controlled device to dispose an alignment fixture on the RGA interposer and disposing the electrical component within the alignment fixture.

In Example 52, the subject matter of any one or more of Examples 46-51 optionally include wherein the instructions cause the computer-controlled device to reflow the solid solder bumps.

In Example 53, the subject matter of Example 52 optionally includes wherein the instructions cause the computer-controlled device to reflow a plurality of electrical component solder bumps on the electrical component to form electrical contacts between the plurality of electrical component solder bumps and the solid solder bumps.

In Example 54, the subject matter of any one or more of Examples 45-53 optionally include wherein the instructions cause the computer-controlled device to dispose solder in each of a plurality of vacant spaces within an interposer contact mask, the plurality of vacant spaces corresponding to the plurality of interposer contacts.

In Example 55, the subject matter of Example 54 optionally includes wherein the instructions cause the computer-controlled device to dispose a solder resist material.

In Example 56, the subject matter of any one or more of Examples 54-55 optionally include wherein the interposer contact mask includes a dielectric material.

In Example 57, the subject matter of Example 56 optionally includes wherein the dielectric material includes a fiberglass material.

In Example 58, the subject matter of any one or more of Examples 54-57 optionally include wherein the instructions cause the computer-controlled device to dispose the interposer contact mask on the RGA interposer.

In Example 59, the subject matter of any one or more of Examples 54-58 optionally include wherein the interposer contact mask is formed on the RGA interposer.

In Example 60, the subject matter of any one or more of Examples 44-59 optionally include wherein the instructions cause the computer-controlled device to dispose a solder film on the RGA interposer, the solder film applying a pre-dispensed solder paste deposit on each of a plurality of interposer contacts.

In Example 61, the subject matter of Example 60 optionally includes wherein the solder film is shaped to align with the RGA interposer to align the pre-dispensed solder paste deposit with the plurality of interposer contacts.

Example 62 is at least one machine-readable storage medium, comprising a plurality of instructions that, responsive to being executed with processor circuitry of a computer-controlled device, cause the computer-controlled device to: apply flux to solid solder bumps on a reflow grid array (RGA) interposer; dispose an electrical component on the RGA interposer; and solder the electrical component to the RGA interposer.

In Example 63, the subject matter of Example 62 optionally includes wherein the electrical component includes a ball grid array (BGA) component.

In Example 64, the subject matter of any one or more of Examples 62-63 optionally include wherein the instructions cause the computer-controlled device to reflow the solid solder bumps.

In Example 65, the subject matter of Example 64 optionally includes wherein the instructions cause the computer-controlled device to reflow a plurality of electrical component solder bumps on the electrical component to form electrical contacts between the plurality of electrical component solder bumps and the solid solder bumps.

In Example 66, the subject matter of any one or more of Examples 62-65 optionally include wherein the instructions cause the computer-controlled device to align the solid solder bumps with a plurality of component contacts on the electrical component.

In Example 67, the subject matter of Example 66 optionally includes wherein the instructions cause the computer-controlled device to dispose an alignment fixture on the RGA interposer and disposing the electrical component within the alignment fixture.

Example 68 is an apparatus comprising: means for disposing solder on each of a plurality of interposer contacts on a reflow grid array (RGA) interposer; and means for reflowing the solder to form solid solder bumps, the solid solder bumps configured to be reflowed by the RGA interposer to solder an electrical component to the RGA interposer.

In Example 69, the subject matter of Example 68 optionally includes wherein means for reflowing the solder includes means for heating an interposer heater trace.

In Example 70, the subject matter of any one or more of Examples 68-69 optionally include means for soldering the electrical component to the RGA interposer.

In Example 71, the subject matter of Example 70 optionally includes wherein the electrical component includes a ball grid array (BGA) component.

In Example 72, the subject matter of any one or more of Examples 70-71 optionally include wherein means for soldering the electrical component includes means for applying flux to the solid solder bumps.

In Example 73, the subject matter of Example 72 optionally includes wherein means for soldering the electrical component includes means for disposing the electrical component on the RGA interposer.

In Example 74, the subject matter of any one or more of Examples 72-73 optionally include wherein means for soldering the electrical component includes means for aligning the interposer solid solder bumps with a plurality of component contacts on the electrical component.

In Example 75, the subject matter of Example 74 optionally includes wherein means for aligning the solid solder bumps includes means for disposing an alignment fixture on the RGA interposer and means for disposing the electrical component within the alignment fixture.

In Example 76, the subject matter of any one or more of Examples 70-75 optionally include wherein means for soldering the electrical component includes means for reflowing the solid solder bumps.

In Example 77, the subject matter of Example 76 optionally includes wherein means for soldering the electrical component includes means for reflowing a plurality of electrical component solder bumps on the electrical component to form electrical contacts between the plurality of electrical component solder bumps and the solid solder bumps.

In Example 78, the subject matter of any one or more of Examples 68-77 optionally include wherein means for disposing solder on each of the plurality of interposer contacts includes means for disposing solder in each of a plurality of vacant spaces within an interposer contact mask, the plurality of vacant spaces corresponding to the plurality of interposer contacts.

In Example 79, the subject matter of Example 78 optionally includes wherein means for disposing solder includes means for disposing a solder resist material.

In Example 80, the subject matter of any one or more of Examples 78-79 optionally include wherein the interposer contact mask includes a dielectric material.

In Example 81, the subject matter of Example 80 optionally includes wherein the dielectric material includes a fiberglass material.

In Example 82, the subject matter of any one or more of Examples 78-81 optionally include wherein means for disposing solder includes means for disposing the interposer contact mask on the RGA interposer.

In Example 83, the subject matter of any one or more of Examples 78-82 optionally include wherein the interposer contact mask is formed on the RGA interposer.

In Example 84, the subject matter of any one or more of Examples 68-83 optionally include wherein means for disposing the solder includes means for disposing a solder film on the RGA interposer, the solder film applying a pre-dispensed solder paste deposit on each of a plurality of interposer contacts.

In Example 85, the subject matter of Example 84 optionally includes wherein the solder film is shaped to align with the RGA interposer to align the pre-dispensed solder paste deposit with the plurality of interposer contacts.

Example 86 is an apparatus comprising: means for applying flux to solid solder bumps on a reflow grid array (RGA) interposer; means for disposing an electrical component on the RGA interposer; and means for soldering the electrical component to the RGA interposer.

In Example 87, the subject matter of Example 86 optionally includes wherein the electrical component includes a ball grid array (BGA) component.

In Example 88, the subject matter of any one or more of Examples 86-87 optionally include wherein means for soldering the electrical component includes means for reflowing the solid solder bumps.

In Example 89, the subject matter of Example 88 optionally includes wherein means for soldering the electrical component includes means for reflowing a plurality of electrical component solder bumps on the electrical component to form electrical contacts between the plurality of electrical component solder bumps and the solid solder bumps.

In Example 90, the subject matter of any one or more of Examples 86-89 optionally include wherein means for soldering the electrical component includes means for aligning the interposer solid solder bumps with a plurality of component contacts on the electrical component.

In Example 91, the subject matter of Example 90 optionally includes wherein means for aligning the solid solder bumps includes means for disposing an alignment fixture on the RGA interposer and means for disposing the electrical component within the alignment fixture. These and other examples and features of the present molds, mold systems, and related methods will be set forth in part in the following detailed description. This overview is intended to provide non-limiting examples of the present subject matter—it is not intended to provide an exclusive or exhaustive explanation. The detailed description below is included to provide further information about the present molds, mold systems, and methods.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. In the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A method comprising:
disposing solder on each of a plurality of interposer contacts on a reflow grid array (RGA) interposer; and
reflowing the solder to form solid solder bumps, the solid solder bumps configured to be reflowed by the RGA interposer to solder an electrical component to the RGA interposer.

2. The method of 1, wherein reflowing the solder includes heating an interposer heater trace.

3. The method of claim 1, further including soldering the electrical component to the RGA interposer.

4. The method of claim 3, wherein soldering the electrical component includes applying flux to the solid solder bumps.

5. The method of claim 4, wherein soldering the electrical component includes aligning the solid solder bumps with a plurality of component contacts on the electrical component.

6. The method of claim 5, wherein aligning the solid solder bumps includes disposing an alignment fixture on the RGA interposer and disposing the electrical component within the alignment fixture.

7. The method of claim 3, wherein soldering the electrical component includes reflowing the solid solder bumps.

8. The method of claim 7, wherein soldering the electrical component includes reflowing a plurality of electrical component solder bumps on the electrical component to form electrical contacts between the plurality of electrical component solder bumps and the solid solder bumps.

9. The method of claim 1, wherein disposing solder on each of the plurality of interposer contacts includes disposing solder in each of a plurality of vacant spaces within an interposer contact mask, the plurality of vacant spaces corresponding to the plurality of interposer contacts.

10. A method comprising:
applying flux to solid solder bumps on a reflow grid array (RGA) interposer;
disposing an electrical component on the RGA interposer; and
soldering the electrical component to the RGA interposer.

11. The method of claim 10, wherein soldering the electrical component includes reflowing the solid solder bumps.

12. The method of claim 11, wherein soldering the electrical component includes reflowing a plurality of electrical component solder bumps on the electrical component to form electrical contacts between the plurality of electrical component solder bumps and the solid solder bumps.

13. The method of claim 10, wherein soldering the electrical component includes aligning the solid solder bumps with a plurality of component contacts on the electrical component.

14. An apparatus comprising:
a reflow grid array (RGA) interposer including a heater trace and a plurality of interposer contacts;
solid solder bumps reflowed on each of the plurality of interposer contacts.

15. The apparatus of claim 14, further including an electrical component soldered to the RGA interposer, wherein the heating element is configured to reflow the solid solder bumps to solder the electrical component to the RGA interposer.

16. The apparatus of claim 15, further including an alignment fixture to align the electrical component with the RGA interposer.

17. An apparatus comprising:
a reflow grid array (RGA) interposer including a heater trace and a plurality of interposer contacts; and
an RGA interposer solder application device to facilitate application of a solder deposit to each of the plurality of interposer contacts, the heater trace configured to reflow the solder deposit to form solid solder bumps on each of the plurality of interposer contacts.

18. The apparatus of claim 17, wherein the RGA interposer solder application device includes an interposer contact mask, the interposer contact mask including a plurality of mask spaces corresponding to the plurality of interposer contacts.

19. The apparatus of claim 18, wherein the interposer contact mask includes a contact mask solder deposit within each of the plurality of mask spaces.

20. The apparatus of claim 17, wherein the RGA interposer solder application device includes a solder film, the solder film configured to dispose a solder film solder deposit on each of the plurality of interposer contacts.
